(19) United States
(12) Patent Application Publication
(10) Pub. No.: US 2026/0092399 A1
(43) Pub. Date: Apr. 2, 2026

(54) METHOD FOR FORMING AN EPITAXIAL STRUCTURE ONTO A SUBSTRATE AND SUBSTRATE PROCESSING APPARATUS

(71) Applicant: ASM IP Holding B.V., Almere (NL)

(72) Inventors: Brendan Marozas, Leuven (BE); Rami Khazaka, Leuven (BE); René Henricus Jozef Vervuurt, Leuven (BE)

(21) Appl. No.: 19/342,449

(22) Filed: Sep. 26, 2025

Related U.S. Application Data
(60) Provisional application No. 63/700,207, filed on Sep. 27, 2024.

(51) Int. Cl. C30B 29/06; C30B 25/12; C30B 25/16; C30B 25/18; C30B 25/20; C30B 29/52

(52) U.S. Cl. CPC C30B 29/06; C30B 25/12; C30B 25/16; C30B 25/186; C30B 25/20; C30B 29/52

(57) ABSTRACT

This disclosure relates to a method for forming an epitaxial structure onto a substrate, a substrate processing apparatus, a computer program, and a non-transitory computer-readable medium. The method comprises providing the substrate in a process chamber and forming an epitaxial layer onto the substrate by exposing the substrate in the process chamber to at least one precursor in the presence of active species.

This Application claims the benefit of U.S. Provisional Application 63/700,207 filed on Sep. 27, 2024, the entire contents of which are incorporated herein by reference.

### TECHNICAL FIELD

This disclosure generally relates to the fields of microfabrication and nanofabrication. In particular, the present disclosure relates to the field of semiconductor manufacturing technology, for example, the fabrication of integrated circuits.

### BACKGROUND

The manufacturing methods of advanced semiconductor devices have been studied extensively in recent years due to the increasing demand for higher performance and miniaturization in electronic components. Epitaxial chemical vapor deposition is essential for the fabrication of high-quality semiconductor materials, for example, in the formation of multilayer structures. It is generally accepted that utilization of multilayer structures comprising silicon (Si) and silicon-germanium (SiGe) layers may offer significant advantages in various semiconductor manufacturing workflows. However, some conventional solutions for epitaxial deposition of Si-SiGe multilayer structures may encounter challenges related, for example, to lattice mismatch, defect formation, and/or interface roughness, which can adversely affect device performance. Additionally, achieving precise control over the composition and thickness of each layer in a multilayer stack remains a significant challenge, especially at higher growth rates. In light of the above, it may be desirable to develop novel solutions related to the epitaxial deposition of Si-SiGe multilayer stacks.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

According to a first aspect, a method for forming an epitaxial structure onto a substrate is provided. The method comprises providing the substrate in a process chamber and forming an epitaxial layer onto the substrate by exposing the substrate in the process chamber to at least one precursor in the presence of active species.

According to a second aspect, a substrate processing apparatus is provided. The substrate processing apparatus comprises a process chamber configured to hold a substrate, a precursor source for providing at least one precursor in the process chamber, and a plasma source for providing active species in the process chamber. The substrate processing apparatus comprises a control unit operably coupled to at least the process chamber, the precursor source, and the plasma source. The control unit is configured to cause the substrate processing apparatus to perform a method in accordance with the first aspect.

According to a third aspect, a computer program is provided. The computer program is configured to cause a substrate processing apparatus in accordance with the second aspect to execute a method in accordance with the first aspect.

According to a fourth aspect, a non-transitory computer-readable medium is provided. The non-transitory computer-readable medium is used for, adapted for, and/or configured for storing a computer program in accordance with the third aspect.

In some embodiments, the process of forming an epitaxial layer comprises maintaining a plasma at a plasma power per exposed substrate area less than or equal to 0.2 W/cm² to generate the active species.

In some embodiments, the epitaxial structure is implemented as an epitaxial superlattice.

In some embodiments, the epitaxial layer comprises crystalline silicon.

In some embodiments, the epitaxial layer has a layer thickness greater than or equal to 1 nm or to 3 nm, or to 5 nm and/or less than or equal to 10 nm, or to 20 nm, or to 30 nm, or to 40 nm, or to 50 nm.

In some embodiments, the substrate comprises a semiconductor wafer, such as a silicon wafer.

In some embodiments, the semiconductor wafer has a diameter of about 200 mm, about 300 mm, or about 450 mm.

In some embodiments, the at least one precursor comprises silane.

In some embodiments, the process of forming an epitaxial layer comprises exciting at least one reactant to form the active species. In some embodiments, the process of exciting at least one reactant comprises exposing the active species to plasma.

In some embodiments, the at least one reactant comprises hydrogen gas.

In some embodiments, the active species comprise hydrogen radicals and/or hydrogen ions.

In some embodiments, the process of forming an epitaxial layer comprises maintaining a plasma at a plasma power per exposed substrate area greater than or equal to 0.01 W/cm², or to 0.02 W/cm², or to 0.03 W/cm², or to 0.04 W/cm², or to 0.05 W/cm² and/or less than or equal to 0.1 W/cm², or to 0.13 W/cm², or to 0.15 W/cm², or to 0.17 W/cm² to generate the active species. In some embodiments the process of forming an epitaxial layer comprises maintaining a plasma at a plasma power per exposed substrate area greater than or equal to 0.01 W/cm², or to 0.02 W/cm², or to 0.03 W/cm², or to 0.04 W/cm², or to 0.05 W/cm² and/or less than or equal to 0.1 W/cm², or to 0.13 W/cm², or to 0.15 W/cm², or to 0.17 W/cm², or to 0.2 W/cm², or to 0.5 W/cm², or to 1 W/cm², or to 2 W/cm² to generate the active species.

In some embodiments, the process of forming an epitaxial layer comprises generating the active species in the process chamber.

In some embodiments, the process of forming an epitaxial layer comprises maintaining a deposition pressure greater than or equal to 160 Pa, or to 200 Pa, or to 240 Pa, or to 280 Pa and/or less than or equal to 420 Pa, or to 460 Pa, or to 500 Pa in the process chamber.

In some embodiments, the process of forming an epitaxial layer comprises maintaining a deposition temperature greater than or equal to 100° C., or to 120° C., or to 150° C. and/or less than or equal to 180° C., or to 190° C., or to 200° C., or to 250° C., or to 300° C., or to 400° C., or to 500° C., or to 600° C., or to 700° C. in the process chamber.

In some embodiments, the method comprises precleaning the substrate prior to the process of forming an epitaxial layer.

In some embodiments, the process of precleaning the substrate comprises providing the substrate in a preclean chamber, and the process of providing the substrate in a process chamber comprises transferring the substrate from the preclean chamber to the process chamber under vacuum.

In some embodiments, the method comprises forming a second epitaxial layer onto the epitaxial layer by exposing the epitaxial layer in the process chamber to one or more precursors in the presence of second active species.

In some embodiments, the second epitaxial layer comprises silicon germanium.

In some embodiments, the second epitaxial layer has a layer thickness greater than or equal to 1 nm or to 3 nm, or to 5 nm and/or less than or equal to 10 nm, or to 20 nm, or to 30 nm, or to 40 nm, or to 50 nm.

In some embodiments, the one or more precursors comprises silane and germane.

In some embodiments, the process of forming a second epitaxial layer comprises exciting one or more reactants to form the second active species. In some embodiments, the process of exciting one or more reactants comprises exposing the second active species to plasma.

In some embodiments, the one or more reactants comprises hydrogen gas.

In some embodiments, the second active species comprise hydrogen radicals and/or hydrogen ions.

In some embodiments, the process of forming a second epitaxial layer comprises maintaining a second plasma at a second plasma power per exposed substrate area greater than or equal to 0.01 W/cm², or to 0.02 W/cm², or to 0.03 W/cm², or to 0.04 W/cm², or to 0.05 W/cm² and/or less than or equal to 0.1 W/cm², or to 0.13 W/cm², or to 0.15 W/cm², or to 0.17 W/cm², or to 0.2 W/cm², or to 0.5 W/cm², or to 1 W/cm², or to 2 W/cm² to generate the second active species.

In some embodiments, the process of forming a second epitaxial layer comprises generating the second active species in the process chamber.

In some embodiments, the process of forming a second epitaxial layer comprises maintaining a second deposition pressure greater than or equal to 160 Pa, or to 200 Pa, or to 240 Pa, or to 280 Pa and/or less than or equal to 420 Pa, or to 460 Pa, or to 500 Pa in the process chamber.

In some embodiments, the process of forming a second epitaxial layer comprises maintaining a second deposition temperature greater than or equal to 100° C., or to 120° C., or to 150° C. and/or less than or equal to 180° C., or to 190° C., or to 200° C., or to 250° C., or to 300° C., or to 400° C., or to 500° C., or to 600° C., or to 700° C. in the process chamber.

In some embodiments, the substrate processing apparatus is configured for concurrently forming an epitaxial layer onto the substrate and forming one or more further epitaxial layers onto one or more further substrates.

In some embodiments, the process chamber comprises a substrate holder configured to hold a semiconductor wafer having a maximum diameter of about 200 mm, about 300 mm, or about 450 mm.

In some embodiments, the substrate processing apparatus comprises a reactant source for providing one or more reactants in the process chamber.

In some embodiments, the substrate processing apparatus comprises a preclean chamber coupled with the process chamber to allow transferring the substrate from the preclean chamber to the process chamber under vacuum.

### DESCRIPTION OF THE DRAWINGS

A more complete understanding of the embodiments of the present disclosure may be derived by referring to the detailed description and claims when considered in connection with the following illustrative figures:

FIG. 1 illustrates a method for forming an epitaxial structure onto a substrate;

FIG. 2A, FIG. 2B, FIG. 2C, and FIG. 2D schematically illustrate a series of successive stages of a method for forming an epitaxial structure onto a substrate;

FIG. 3 depicts a substrate processing apparatus; and

FIG. 4 shows another substrate processing apparatus.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

The illustrations presented herein are not meant to be actual views of any particular material, structure, or device, but are merely idealized representations that are used to describe embodiments of the disclosure.

For clarity and brevity, consistent reference numerals may be used throughout the figures for corresponding, similar, and/or identical elements.

### DETAILED DESCRIPTION

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail or omitted entirely. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and sub-combinations of the various processes, systems, and configurations, and other features, functions, acts, and/or properties disclosed herein, as well as any and all equivalents thereof.

Throughout this specification, “epitaxy” may refer to a type of crystal growth or layer formation on a substrate where the deposited layer mimics or conforms to the crystallographic structure of the substrate. In some embodiments, epitaxial growth may involve the deposition of semiconductor materials, such as silicon, gallium arsenide, or other compound semiconductors. Additionally or alternatively, epitaxy may refer to the process of growing a crystalline layer on a crystalline substrate. Herein, a “layer” may refer to a structure having a certain thickness formed on a surface. A layer may be continuous or discontinuous. A layer may or may not be constituted by a discrete single layer having certain characteristics or multiple layers. A boundary between adjacent layers may or may not be clear and may or may not be established based on physical, chemical, and/or any other characteristics, formation processes or sequences, and/or functions or purposes of the adjacent layers. A layer may or may not comprise pinholes. A layer may or may not be porous. Consequently, an “epitaxial layer” may refer to a layer formed by epitaxy. Additionally or alternatively, an epitaxial layer may refer to a crystalline layer grown on a crystalline substrate, wherein the epitaxial layer mimics or conforms to the crystallographic structure of the substrate.

In this disclosure, a “structure” may refer to an arrangement or organization of interrelated elements in a material object or system. In some embodiments, a structure may comprise layers, patterns, and/or configurations of materials that provide specific physical, chemical, and/or electrical properties. As such, an “epitaxial structure” may refer to a structure comprising one or more epitaxial layers formed on a substrate. Additionally or alternatively, an epitaxial structure may refer to a structure where the epitaxial layer(s) have a crystallographic orientation that is aligned with the underlying substrate. In some embodiments, an epitaxial structure may comprise multiple epitaxial layers of different materials, each layer having a specific thickness, composition, and crystallographic orientation. Additionally or alternatively, an epitaxial structure may refer to a semiconductor device or component that includes one or more epitaxial layers, such as transistors, diodes, or integrated circuits. In some embodiments, an epitaxial structure may comprise one or more doped regions, where dopants are introduced into the epitaxial layer(s) to modify their electrical properties. Additionally or alternatively, an epitaxial structure may comprise one or more patterned regions, where specific areas of the epitaxial layer(s) are selectively etched or deposited to create desired features or devices. In some embodiments, an epitaxial structure may include one or more interfaces between different epitaxial layers or between an epitaxial layer and the substrate, where the properties of these interfaces may be critical to the performance of the structure.

In this specification, a “superlattice” may refer to a stacked structure, e.g., a periodically or non-periodically stacked structure, of layers of two or more materials, for example, semiconductor materials, with thicknesses ranging from a few ångströms (Å) to tens of nanometers (nm). Consequently, an “epitaxial superlattice” may refer to a superlattice structure where the individual layers are formed using epitaxy on a substrate. Additionally or alternatively, an epitaxial superlattice may refer to a structure comprising multiple epitaxial layers of different materials, arranged in a periodic manner, where each layer has a crystallographic orientation aligned with its underlying material. In some embodiments, an epitaxial superlattice may be designed to achieve specific electronic, optical, and/or mechanical properties by carefully controlling the thickness, composition, and/or sequence of the epitaxial layers.

In this disclosure, a “process” may refer to a series of one or more steps, leading to an end result. Additionally or alternatively, a process may refer to a sequence of steps designed to achieve a specific objective. In some embodiments, a process may be a single-step process or a multistep process. Additionally or alternatively, a process may be divisible into a plurality of sub-processes, wherein individual sub-processes of such plurality of sub-processes may or may not share common steps. In some embodiments, a process may involve iterative steps, feedback loops, or conditional steps based on predefined criteria. Herein, a “sub-process” may refer to a subset of steps within a larger process, which can function independently or in conjunction with other sub-processes. Additionally or alternatively, a sub-process may be defined by its specific role or function within the overall process. In some embodiments, sub-processes may be nested within other sub-processes, creating a hierarchical structure of steps. Further, the term “end result” may refer to the final outcome or product achieved through the execution of a process. Additionally or alternatively, an end result may refer to an intermediate outcome that serves as a precursor to subsequent steps or processes. In some embodiments, an end result may be quantifiable, such as a measurable change in a physical property, or qualitative, such as an improvement in performance or efficiency. Further, a “step” may refer to a measure taken in order to achieve one or more pre-defined end results. In some embodiments, a step may involve physical actions, chemical reactions, data processing, or any combination thereof. Additionally or alternatively, a step may be performed manually, automatically, or semi-automatically.

Throughout this specification, a “chamber” may refer to an enclosed, openable, isolatable, and/or separable space suitable or configured for containing and/or processing one or more substrates. Further, a “process chamber” may refer to a chamber suitable or configured for conducting one or more chemical (e.g., epitaxial) processes. Additionally or alternatively, a process chamber may refer to a chamber suitable for or configured to facilitate chemical (e.g., epitaxial) reactions under controlled conditions. Additionally or alternatively, a process chamber may refer to a chamber comprising one or more inlets and/or outlets for introducing and/or removing one or more substances therefrom, the one or more substances comprising, for example, solid, liquid, and/or gaseous substances. Additionally or alternatively, a process chamber may refer to a chamber suitable or configured for depositing an epitaxial layer on a substrate through a chemical vapor deposition process. Additionally or alternatively, a process chamber may refer to a process chamber suitable for or configured to supply at least one precursor to a substrate to form an epitaxial layer. Additionally or alternatively, a process chamber may refer to a chamber defined by one or more of physical barrier(s), and/or gas bearing(s), and/or gas curtain(s). Additionally or alternatively, a process chamber may refer to a chamber configured to be fluidically separated and/or isolated from other process chambers, while the process chamber is in use. In some embodiments, a process chamber may comprise one or more gas inlets for introducing at least one precursor, one or more gas outlets for removing reaction by-products and/or unused portions of at least one precursor, and/or a substrate holder for positioning a substrate during a deposition process. In some embodiments, a process chamber may comprise one or more temperature control elements, such as one or more heating elements, and/or one or more cooling elements; and/or one or more pressure control elements, such as one or more vacuum pumps and/or pressure sensors. In some embodiments, a process chamber may comprise one or more gas flow control elements, such as one or more mass flow controllers and/or valves.

In this specification, the term “substrate” may refer to a base material on which epitaxial growth occurs. In some embodiments, a substrate may be comprise, consist substantially of, or consist of one or more single-crystal materials, such as silicon, germanium, sapphire, and/or gallium arsenide. Additionally or alternatively, a substrate may refer to an article that provides mechanical support and/or crystallographic structure for an epitaxial layer. In some embodiments, a substrate may comprise a semiconductor wafer. In some embodiments, a substrate may comprise one or more epitaxial layers, e.g., a buffer layer.

In this specification, a “semiconductor wafer” may refer to a slice of one or more semiconductor materials, such as silicon, gallium arsenide, silicon carbide, and/or indium phosphide. In some embodiments, a semiconductor wafer may have a circular or rectangular shape. In some embodiments, a semiconductor wafer may have a thickness in a range from about 275 micrometers (μm) to 925 μm. In some embodiments, smaller or larger thicknesses may also be used depending on specific application and technology requirements. In embodiments, wherein a semiconductor wafer has a circular shape, the semiconductor wafer may have any suitable diameter, for example, a diameter in a range from 51 mm (2 inches) to 450 mm (17.7 inches). In some embodiments, smaller or larger diameters may also be used depending on specific application and technology requirements. In embodiments, wherein a semiconductor wafer has a rectangular shape, the semiconductor wafer may have any suitable lateral dimensions, for example, lateral dimensions in a range from 50 mm×50 mm to 600 mm×600 mm. In some embodiments, smaller or larger lateral dimensions may also be used depending on specific application and technology requirements.

Throughout this specification, a “species” may refer to a chemical species, such as a chemical compound, a molecular structural unit of a solid array, or a molecular entity. Additionally or alternatively, species may refer to one or more structurally distinct atoms, molecules, ions, radicals, or complexes. Herein, an “ion” may refer to an atomic or molecular particle possessing a net electric charge, and/or a “radical” may refer to an atomic or molecular particle possessing an unpaired electron. Further, “active species” may refer to unstable species formed in plasma, via interactions with catalytic material(s) at elevated temperatures, and/or by other suitable means. Additionally or alternatively, active species may refer to ions, radicals, and/or molecules excited by a plasma.

Throughout this specification, “plasma” may refer to a partially or fully ionized gas containing ions and electrons and, optionally, neutral particles. Additionally or alternatively, plasma may refer to a state of matter, wherein a gas phase is energized until at least part of atomic electrons is no longer associated with any particular atomic nucleus. In some embodiments, plasma may be generated using radio frequency (RF) or microwave power sources.

Consequently, a “plasma source” may refer to a device or system suitable for or configured for generating plasma. Additionally or alternatively, a plasma source may refer to device or system suitable for or configured to providing active species in a process chamber. In some embodiments, a plasma source may be configured for generating plasma at least partly via radio-frequency excitation, for example, via capacitively coupled radio-frequency electromagnetic waves and/or inductively coupled radio-frequency electromagnetic waves. In some such embodiments, the plasma source may be configured to utilize one or more radio-frequency excitation frequencies, for example, one or more frequencies greater than or equal to 20 kHz, or to 50 kHz, or to 100 kHz, or to 300 kHz, or to 500 kHz, or to 1 MHz and/or less than or equal to 50 MHz, or to 100 MHz, or to 300 MHz, or to 500 MHz, or to 1 GHz for generating plasma. In some embodiments, a plasma source may be configured for generating plasma at least partly via microwave excitation, for example, via electron cyclotron resonance. In some embodiments, a plasma source may be configured for generating plasma at least partly via surface wave excitation. In some embodiments, a plasma source may be configured for in-situ generation of active species and/or ex-situ (remote) generation of active species. In such embodiments, a plasma source may be implemented as an in-situ and/or remote a plasma source, respectively.

In this disclosure, the term “exposed substrate area” may refer to the surface area of one or more substrates arranged inside a process chamber and exposed to active species therein, for example, during the process of forming an epitaxial layer. Additionally or alternatively, exposed substrate area may refer to a maximum exposed substrate area of one or more substrates that can be held by a process chamber and may be exposed to active species therein, for example, during the process of forming an epitaxial layer. Additionally or alternatively, exposed substrate area may refer to a maximum exposed substrate area of one or more substrates that a process chamber is configured to hold such that the of one or more substrates may be exposed to active species therein, for example, during a process of forming an epitaxial layer. In some embodiments, exposed substrate area may be measured by disregarding the surface area of microscopic and/or nanoscopic surface features, such as recesses, holes, pillars, pores, and/or the like. In some embodiments, wherein each of one or more substrates comprises a semiconductor wafer, exposed substrate area of the one or more substrates may be defined by the lateral dimensions (e.g., diameter) of the semiconductor wafers and/or the number of wafer faces that may be exposed to active species therein, for example, during a process of forming an epitaxial layer. In some embodiments, wherein a substrate comprises a semiconductor wafer arranged onto a substrate holder shielding a wafer face of the semiconductor wafer from exposure to active species, exposed substrate area may be defined solely by the lateral dimensions (e.g., diameter) of an unshielded wafer face of the semiconductor wafer. Herein, a “wafer face” may refer to a polished face of a semiconductor wafer. Additionally or alternatively, a “wafer face” may refer to a face of a semiconductor wafer suitable or configured for microfabrication, nanofabrication, and/or semiconductor manufacturing.

In this specification, “power” may refer to the rate at which energy is transferred or converted. In some embodiments, power may refer to instantaneous power. In some embodiments, power may refer to time-averaged power. In some such embodiments, such time-averaged power may be averaged over a time period of pre-determined duration, e.g., a duration of 1 microsecond (μs), 10 μs, 50 μs, 100 μs, 500 μs, 1 millisecond (ms), 10 ms, 50 ms, 100 ms, 500 ms, 1 second(s), 2 s, 5 s, or 10 s. In some embodiments, a time-averaged power may be averaged over one or more power signal duty cycles and/or over one or more power signal periods. Further, “plasma power” may refer to the power applied to a plasma using electromagnetic radiation. Additionally or alternatively, plasma power may refer to the power applied to a plasma to maintain the plasma, for example, under steady-state conditions or under quasi-steady-state conditions. Additionally or alternatively, plasma power may refer to the power applied to a plasma to maintain the plasma following plasma ignition. Additionally or alternatively, plasma power may refer to power delivered by active species to one or more exposed substrates, for example, during a process of forming an epitaxial layer.

Throughout this specification, a “precursor” may refer to a chemical compound that participates in a chemical reaction to produce another compound. In some embodiments, said chemical reaction may occur in a vapor phase. Additionally or alternatively, a precursor may refer to a compound that is introduced into a process chamber in gaseous form. Additionally or alternatively, a precursor may refer to a compound that, upon decomposition or reaction, forms a desired material on a substrate. Additionally or alternatively, a precursor may refer to a chemical compound suitable or configured for forming an epitaxial layer on a substrate. Additionally or alternatively, a precursor may refer to a compound that, when introduced into a process chamber, decomposes or reacts to form an epitaxial layer on a substrate. In some embodiments, a precursor may comprise a metal-organic compound, a hydride, or a halide. In some embodiments, a precursor may be supplied in gaseous form. In some embodiments, a precursor it may be volatilized (e.g., vaporized or sublimated) from a liquid or solid form before introduction into a process chamber. In some embodiments, a precursor may be introduced into a process chamber using a carrier gas. In some such embodiments, the carrier gas may comprise one or more inert gases, such as nitrogen, helium, neon, and/or argon.

In this disclosure, a “precursor source” may refer to a device or system suitable or configured for providing at least one precursor to a process chamber. Additionally or alternatively, a precursor source may refer to a device or system configured to vaporize one or more liquid and/or solid precursors before introduction into a process chamber. Additionally or alternatively, a precursor source may refer to a device or system that includes one or more precursor delivery lines for transporting at least one precursor from one or more storage containers to a process chamber. Additionally or alternatively, a precursor source may refer to a device or system suitable or configured for supplying a precursor in gaseous form to a process chamber for forming an epitaxial layer on a substrate. In some embodiments, a precursor source may comprise one or more precursor containers or vessels for storing at least one precursor in liquid, solid, and/or gaseous form(s). In some embodiments, a precursor source may comprise a carrier gas supply system for introducing a carrier gas into a process chamber along with a precursor. In some embodiments, a precursor source may comprise one or more flow control valves for regulating the flow of one or more precursors into a process chamber. In some embodiments, a precursor source may comprise one or more sensors, such as temperature sensors and/or pressure sensors, for monitoring the conditions within one or more precursor containers or vessels.

Throughout this specification, “precleaning” may refer to a process of cleaning and/or treating a surface of a substrate prior to and/or in preparation for forming an epitaxial layer. Herein, “cleaning” may refer to the removal of unwanted material(s) from a surface, and/or “treating” may refer to the application of a process to modify the properties of a surface. Additionally or alternatively, precleaning may refer to removing oxygen-containing compounds for a surface of a substrate. Additionally or alternatively, precleaning may refer to removing oxide(s), e.g., native oxide(s), from a surface of a substrate. Additionally or alternatively, precleaning may refer to removing contaminants, e.g., oxygen, carbon, fluorine, and/or the like, disposed on a surface of a substrate. Additionally or alternatively, precleaning may refer to providing a passivated surface for a substrate. Additionally or alternatively, precleaning may refer to providing a hydrophobic surface for a substrate. Additionally or alternatively, precleaning may refer to plasma cleaning, wet chemical cleaning, hydrogen annealing, and/or thermal desorption. In some embodiments, precleaning may comprise using specific species, such as hydrogen, ammonia, hydrogen fluoride, one or more ionic species, and/or one or more radical species, to achieve a clean and prepared substrate surface for epitaxy.

Throughout this disclosure, a “control unit” may refer to a device or system possessing at least one designated function associated with determining and/or influencing one or more operational conditions, states, and/or parameters pertaining to another device, unit, or component. Additionally or alternatively, a control unit may refer to a device or system that receives one or more input signals from one or more sensors and/or generates one or more output signals to control one or more actuators. Additionally or alternatively, a control unit may refer to a device or system that executes one or more control algorithms to maintain desired process conditions for a substrate processing apparatus. Additionally or alternatively, a control unit may refer to a device or system suitable or configured for controlling parameters such as temperature, pressure, gas flow rates, plasma power, and/or the like in a substrate processing apparatus. Additionally or alternatively, a control unit may refer to a device or system that interfaces with an operator to allow manual adjustments of process parameters. In some embodiments, a control unit may be implemented as an electronic device. In some embodiments, a control unit may comprise hardware and/or software components. In some embodiments, a control unit may include a programmable logic controller (PLC) or a computer-based control system. In some embodiments, a control unit may be integrated with a data acquisition system to monitor and record process data. In some embodiments, a control unit may include safety interlocks to prevent unsafe operating conditions. In some embodiments, a control unit may form an integral part of a multifunction control system.

Further, the phrase “control unit is configured to” execute a process may refer to the control unit being capable of, appropriate for, and/or adapted for executing the process. Additionally or alternatively, a control unit being configured to execute a process may also refer to any functionally described attributes of the control unit being executed, at least partially, by one or more hardware logic components. In some embodiments, a control unit may comprise at least one processor and at least one memory connected to the said processor. In some such embodiments, the memory may store program code instructions that, upon execution on the processor, prompt the processor to undertake a process that the control unit is configured to execute. In some embodiments, a control unit may comprise one or more hardware logic components. In some such embodiments, the one or more hardware logic components may include, for example, Field Programmable Gate Arrays (FPGAs), Application Specific Integrated Circuits (ASICs), Application Specific Standard Products (ASSPs), System on a Chips (SoCs), Complex Programmable Logic Devices (CPLDs), and the like. A control unit may generally function according to any suitable principles and via any suitable circuitry and/or signals recognized in the art.

In some embodiments, the presently described methods, devices, and apparatuses may be useful in the fields of microfabrication and nanofabrication. In some embodiments, the presently described methods, devices, and apparatuses may be useful in the fields of microelectromechanical systems, microsystems, photonics, photovoltaics, display devices, and/or semiconductor manufacturing technology. In some embodiments, the presently described methods, devices, and apparatuses may be beneficial for forming epitaxial structures, for example, at least partly by chemical vapor deposition. In some embodiments, they may be applied to manufacturing silicon-based electronics, including memory devices, microprocessors, and sensors. In some embodiments, the presently described methods, devices, and apparatuses may be useful for epitaxial deposition of Si-SiGe multilayer structures.

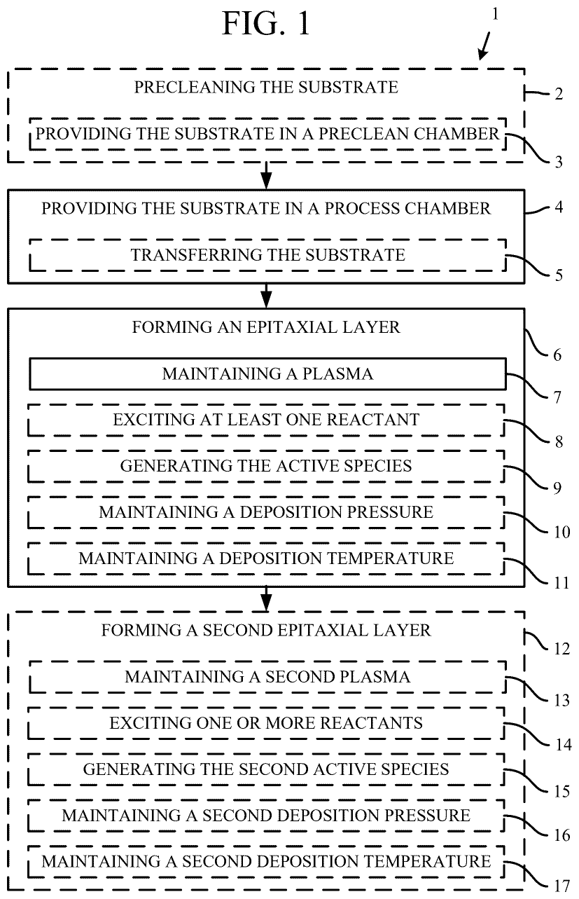

FIG. 1 schematically illustrates a method 1 for forming an epitaxial structure onto a substrate according to an embodiment. Unless explicitly stated otherwise, the method 1 of the embodiment of FIG. 1 may or may not comprise any feature(s) disclosed within this specification, mutatis mutandis. Other embodiments may or may not be identical or similar to the embodiment of FIG. 1. In FIG. 1, many optional features of the method 1 are indicated using dashed lines.

In the embodiment of FIG. 1, the epitaxial structure may be implemented as an epitaxial superlattice. As such, the method 1 of the embodiment of FIG. 1 may serve as an example of a method for forming an epitaxial superlattice. In other embodiments, an epitaxial structure may be implemented in any suitable form, e.g., as an epitaxial superlattice, an epitaxial bilayer, an epitaxial layer, a semiconductor device (e.g., a transistor, a semiconductor memory device, an integrated circuit, or a solar cell), and/or the like.

The method 1 of the embodiment of FIG. 1 comprises providing the substrate in a process chamber 4. In the method 1, a single substrate may be provided in the process chamber. In other embodiments, any suitable number, e.g., one, two, three, four, etc., or one or more, two or more, three or more, etc., or a plurality, of substrates may be provided in a process chamber.

The substrate of the embodiment of FIG. 1 may comprise a semiconductor wafer, such as a silicon wafer. In other embodiments, any suitable type of substrate, e.g., a semiconductor wafer, such as a silicon wafer, a III-V semiconductor wafer, and/or the like, may be used.

In the embodiment of FIG. 1, the semiconductor wafer may have a diameter of about 300 millimeters (mm). In other embodiments, wherein a substrate comprises a semiconductor wafer, the semiconductor wafer may have any suitable lateral dimensions, for example, a diameter of about 200 mm, about 300 mm, or about 450 mm.

In the embodiment of FIG. 1, the method 1 comprises forming an epitaxial layer 6 onto the substrate by exposing the substrate in the process chamber to at least one precursor in the presence of active species.

The epitaxial layer of the embodiment of FIG. 1 may comprise crystalline silicon. In other embodiments, an epitaxial layer may consist of, consist substantially or, or comprise any suitable material(s), for example, semiconductor material(s), e.g., group IV elemental semiconductor(s), such as silicon and/or germanium; group IV compound semiconductor(s), such as silicon germanium; III-V semiconductor(s), such as gallium nitride and/or gallium arsenide; II-VI semiconductor(s), such as cadmium selenide; I-VII semiconductor(s), such as cuprous chloride; IV-VI semiconductor(s), such as tin telluride; V-VI semiconductor(s), such as vanadium oxide; II-V semiconductor(s), such as cadmium arsenide; I-III-Vl2 semiconductor(s), such as copper indium gallium selenide; and/or oxide semiconductor(s); dielectric materials; and/or conductor material(s).

In the embodiment of FIG. 1, the epitaxial layer may have a layer thickness of about 10 nanometers (nm). In other embodiments, an epitaxial layer may have any suitable layer thickness, for example, a layer thickness greater than or equal to 1 nm or to 3 nm, or to 5 nm and/or less than or equal to 10 nm, or to 20 nm, or to 30 nm, or to 40 nm, or to 50 nm.

The at least one precursor of the embodiment of FIG. 1 may comprise silane (SiH₄). In other embodiments, the at least one precursor to which a substrate is exposed during a process of forming an epitaxial layer may consist of, consist substantially or, or comprise any suitable precursor(s), for example, silicon-containing precursor(s), such as silicon hydride(s), for example, silane, linear higher-order silane(s) (e.g., disilane, trisilane, tetrasilane, pentasilane, hexasilane, heptasilane, octasilane, nonasilane, decasilane, and so forth), branched higher-order silane(s) (e.g., neopentasilane, 2-silylpentasilane, 2,2-disilyltetrasilane, 2-silyltrisilane, 2-silyltetrasilane, 3-silylpentasilane, 2,2-disilyltrisilane, 2,3-disilylpentasilane, 2,2,3-trisilylpentasilane, 2,3,4-trisilylpentasilane, 2,3,4-trisilylpentasilane, 2,3-disilyltetrasilane, 2,2,3,3-tetrasilyltetrasilane, 2-silylhexasilane, 3-silylhexasilane, 3,4-disilylhexasilane, 2,3-disilylpentasilane, 2,4-disilylhexasilane, 4-silylheptasilane, 2,2-disilylpentasilane, 3,3-disilylpentasilane, 3,3-disilylhexasilane, 2,2-disilyhexasilane, 2,3-disilylhexsilane, 2-silylheptasilane, 3-silylheptasilane, 2,5-disilyhexasilane, 2,3,3-trisilylpentasilane, and/or the like), cyclic silane(s) (e.g., cyclotrisilane, cyclotetrasilane, cyclopentasilane, cyclohexasilane, cycloheptasilane, and so forth, as well as silyl-substituted variants thereof); and/or silicon hydrohalide(s), for example, monochlorosilane, dichlorosilane, trichlorosilane, 1,2-dichlorodisilane, 1,2,3-trichlorotrisilane and/or the like; and/or silicon halide(s), for example, silicon tetrachloride, silicon tetraiodide, silicon tetrabromide, hexachlorodisilane, octachlorotrisilane, and/or the like; and/or aminosilane(s), for example, hexakis(ethylamino)disilane, bis(diethylamino)silane, di-isopropylaminosilane, and/or the like; and/or oxysilane(s), for example, tetraethoxysilane; and/or germanium-containing precursor(s), such as germanium hydride(s), for example, germane, digermane, trigermane, tetragermane, pentagermane, and so forth, germanium hydrohalide(s), for example, dichlorogermane and/or trichlorogermane, germanium halide(s), for example, germanium tetrachloride, germanium tetrabromide, and/or hexachlorodigermane; and/or silicon-and germanium-containing precursor(s), for example, silicon-germanium hydride(s), such as germylsilane; and/or any at least partly deuterium-substituted variants of any of the above; and/or mixtures of any of the above.

The process of forming an epitaxial layer of the embodiment of FIG. 1 may comprise exciting at least one reactant to form the active species. In particular, the at least one reactant of the embodiment of FIG. 1 may comprise hydrogen gas (H₂). In the embodiment of FIG. 1, hydrogen gas may be supplied into the process chamber, wherein it is subjected to a high-power radiofrequency electromagnetic field to excite hydrogen molecules in the hydrogen gas. Without necessarily limiting the present disclosure to any theory or mode of operation, such excitation may in some embodiments result in the formation of excited hydrogen molecules and/or dissociation of the hydrogen molecules to form excited and/or ground-state hydrogen atoms, radicals, and/or ions. In other embodiments, a process of forming an epitaxial layer may or may not comprise exciting at least one reactant to form active species. Additionally or alternatively, in some embodiments the at least one reactant excited to form active species may consist of, consist substantially or, or comprise any suitable reactant(s), for example, hydrogen gas, deuterium gas, helium, neon, and/or argon. In other embodiments, wherein a process of forming an epitaxial layer comprises exciting at least one reactant to form active species, the process of forming an epitaxial layer may or may not comprise supplying the at least one reactant into a process chamber. For example, in some embodiments, at least one reactant may be excited remotely outside of a process chamber to form active species and the formed active species may be transferred to the process chamber for forming an epitaxial layer.

In the embodiment of FIG. 1, the active species may comprise hydrogen radicals and hydrogen ions. In other embodiments, the active species in whose presence a substrate is exposed to at least one precursor during a process of forming an epitaxial layer may consist of, consist substantially or, or comprise any suitable active species, for example, hydrogen-containing, deuterium-containing, helium-containing, neon-containing, and/or argon-containing active species.

In the embodiment of FIG. 1, the process of forming an epitaxial layer 6 comprises maintaining a plasma 7 at a plasma power per exposed substrate area less than or equal to 0.2 W/cm² to generate the active species. In some embodiments, maintaining a plasma at a sufficiently low plasma power to generate the active species may enable producing high-quality epitaxial layers at reduced temperatures. Additionally or alternatively, in some embodiments maintaining a plasma at a sufficiently low plasma power per exposed substrate area to generate the active species may reduce total energy consumption of a method for forming an epitaxial structure onto a substrate. Additionally or alternatively, in some embodiments maintaining a plasma at a sufficiently low plasma power per exposed substrate area to generate the active species may facilitate forming an epitaxial layer with reduced interlayer diffusion. Additionally or alternatively, in some embodiments maintaining a plasma at a sufficiently low plasma power per exposed substrate area to generate the active species may enable forming an epitaxial layer with reduced surface roughness.

In particular, the process of forming an epitaxial layer 6 of the embodiment of FIG. 1 may comprise maintaining a plasma 7 at a plasma power per exposed substrate area of about 0.15 watts per square centimeter (W/cm²) or about 0.05 W/cm². In other embodiments, a process of forming an epitaxial layer may comprise maintaining a plasma at any suitable plasma power per exposed substrate area, for example, a plasma power greater than or equal to 0.01 W/cm², or to 0.02 W/cm², or to 0.03 W/cm², or to 0.04 W/cm², or to 0.05 W/cm² and/or less than or equal to 0.1 W/cm², or to 0.13 W/cm², or to 0.15 W/cm², or to 0.17 W/cm², or to 0.2 W/cm², or to 0.5 W/cm², or to 1 W/cm², or to 2 W/cm² to generate the active species.

In the embodiment of FIG. 1, the process of forming an epitaxial layer 6 may comprise maintaining a plasma 7 at a plasma power of about 100 W or about 40 W. In other embodiments, a process of forming an epitaxial layer may comprise maintaining a plasma at any suitable plasma power, for example, a plasma power greater than or equal to 5 W, or to 10 W, or to 15 W, or to 20 W and/or less than or equal to 40 W, or to 50 W, or to 60 W, or to 70 W, or to 80 W, or to 90 W, or to 100 W, or to 110 W, or to 120 W, or to 130 W, or to 140 W, or to 150 W, or to 200 W, or to 300 W, or to 400 W, or to 500 W, or to 600 W, or to 700 W, or to 1000 W, or to 1500 W.

In the embodiment of FIG. 1, the process of forming an epitaxial layer 6 may comprise generating the active species 9 in the process chamber. In other embodiments, a process of forming an epitaxial layer may comprise generating the active species in any suitable manner and/or at any suitable location. For example, in some embodiments, a process of forming an epitaxial layer may comprise generating the active species in a process chamber and/or outside of the process chamber. In some embodiments, a process of forming an epitaxial layer may comprise generating the active species using an in-situ plasma source and/or a remote plasma source. In embodiments, wherein a process of forming an epitaxial layer comprises generating the active species in a process chamber and/or using an in-situ plasma source, the active species may be generated using any suitable technique(s) or device(s), for example, radio-frequency plasma source(s), e.g., capacitively coupled plasma source(s) and/or inductively coupled plasma source(s); microwave plasma source(s), e.g., electron cyclotron resonance plasma source(s); surface wave plasma source(s), and/or the like. In embodiments, wherein a process of forming an epitaxial layer comprises generating the active species outside of a process chamber and/or using a remote plasma source, the active species may be generated using any suitable technique(s) or device(s), for example, radio-frequency plasma source(s), e.g., capacitively coupled plasma source(s) and/or inductively coupled plasma source(s); microwave plasma source(s), e.g., electron cyclotron resonance plasma source(s); surface wave plasma source(s), and/or the like.

The process of forming an epitaxial layer 6 of the embodiment of FIG. 1 may comprise maintaining a deposition pressure 10 of about 200 pascals (Pa) or 300 Pa in the process chamber. In some embodiments, maintaining a suitable deposition pressure during a process of forming an epitaxial layer may enable tuning a distribution of active species in the vicinity of a substrate. Additionally or alternatively, in some embodiments maintaining a suitable deposition pressure during a process of forming an epitaxial layer may increase a growth rate of an epitaxial layer. Additionally or alternatively, in some embodiments maintaining a suitable deposition pressure during a process of forming an epitaxial layer may increase a crystallinity of an epitaxial layer. Additionally or alternatively, in some embodiments maintaining a suitable deposition pressure during a process of forming an epitaxial layer may reduce etching while forming an epitaxial layer. In other embodiments, a process of forming an epitaxial layer may comprise maintaining any suitable deposition pressure, for example, a deposition pressure greater than or equal to 160 Pa, or to 200 Pa, or to 240 Pa, or to 280 Pa and/or less than or equal to 420 Pa, or to 460 Pa, or to 500 Pa, in a process chamber.

In the embodiment of FIG. 1, the process of forming an epitaxial layer 6 may comprise maintaining a deposition temperature 11 of about 200 degrees Celsius (° C.), 350° C., or 500° C. In some embodiments, maintaining a suitable deposition temperature may increase a growth rate of an epitaxial layer. Additionally or alternatively, in some embodiments, maintaining a suitable deposition temperature may increase a crystallinity of an epitaxial layer. Additionally or alternatively, in some embodiments, maintaining a suitable deposition temperature may facilitate forming an epitaxial layer with reduced interlayer diffusion. Additionally or alternatively, in some embodiments maintaining a sufficiently low deposition temperature may reduce total energy consumption of a method for forming an epitaxial structure onto a substrate. In other embodiments, a process of forming an epitaxial layer may comprise maintaining any suitable deposition temperature, for example, a deposition temperature greater than or equal to 100° C., or to 120° C., or to 150° C. and/or less than or equal to 180° C., or to 190° C., or to 200° C., or to 250° C., or to 300° C., or to 400° C., or to 500° C., or to 600° C., or to 700° C.

The method 1 of the embodiment of FIG. 1 may comprise precleaning the substrate 2 prior to the process of forming an epitaxial layer 6. In other embodiments, a method for forming an epitaxial structure onto a substrate may or may not comprise precleaning the substrate prior to a process of forming an epitaxial layer.

In the embodiment of FIG. 1, the process of precleaning the substrate 2 may comprise providing the substrate in a preclean chamber 3, and the process of providing the substrate in a process chamber 4 may comprise transferring the substrate 5 from the preclean chamber to the process chamber under vacuum. In some embodiments, precleaning the substrate in a preclean chamber separate from a process chamber may enable separately optimizing the preclean chamber for precleaning the substrate and the process chamber for forming an epitaxial layer. In other embodiments, wherein a method for forming an epitaxial structure onto a substrate comprises precleaning the substrate prior to a process of forming an epitaxial layer, the process of precleaning the substrate may or may not comprise providing the substrate in a preclean chamber, and/or a process of providing the substrate in a process chamber may or may not comprise transferring the substrate from the preclean chamber to the process chamber, for example, under vacuum or under an inert gas (e.g., argon, helium, and/or nitrogen) ambient. In some embodiments, processes of precleaning the substrate and forming an epitaxial layer may be conducted at least partly in the same process chamber.

In the embodiment of FIG. 1, the method 1 may further comprise forming a second epitaxial layer 12 onto the epitaxial layer by exposing the epitaxial layer in the process chamber to one or more precursors in the presence of second active species. In other embodiments, a method for forming an epitaxial structure onto a substrate may or may not comprise forming a second epitaxial layer onto an epitaxial layer by exposing the epitaxial layer in a process chamber to one or more precursors, for example, in the presence of second active species.

The second epitaxial layer of the embodiment of FIG. 1 may comprise, for example, silicon germanium. In other embodiments, a second epitaxial layer may consist of, consist substantially or, or comprise any suitable material(s), for example, semiconductor material(s), e.g., group IV elemental semiconductor(s), such as silicon and/or germanium; group IV compound semiconductor(s), such as silicon germanium; III-V semiconductor(s), such as gallium nitride and/or gallium arsenide; II-VI semiconductor(s), such as cadmium selenide; I-VII semiconductor(s), such as cuprous chloride; IV-VI semiconductor(s), such as tin telluride; V-VI semiconductor(s), such as vanadium oxide; II-V semiconductor(s), such as cadmium arsenide; I-III-Vl2 semiconductor(s), such as copper indium gallium selenide; and/or oxide semiconductor(s); dielectric materials; and/or conductor material(s).

In the embodiment of FIG. 1, the second epitaxial layer may have a layer thickness of about 10 nm. In other embodiments, a second epitaxial layer may have any suitable layer thickness, for example, a layer thickness greater than or equal to 1 nm or to 3 nm, or to 5 nm and/or less than or equal to 10 nm, or to 20 nm, or to 30 nm, or to 40 nm, or to 50 nm.

The one or more precursors of the embodiment of FIG. 1 may comprise silane and germane (GeH₄). In other embodiments, the one or more precursors to which a substrate is exposed during a process of forming a second epitaxial layer may consist of, consist substantially or, or comprise any suitable precursor(s), for example, silicon-containing precursor(s), such as silicon hydride(s), for example, silane, linear higher-order silane(s) (e.g., disilane, trisilane, tetrasilane, pentasilane, hexasilane, heptasilane, octasilane, nonasilane, decasilane, and so forth), branched higher-order silane(s) (e.g., neopentasilane, 2-silylpentasilane, 2,2-disilyltetrasilane, 2-silyltrisilane, 2-silyltetrasilane, 3-silylpentasilane, 2,2-disilyltrisilane, 2,3-disilylpentasilane, 2,2,3-trisilylpentasilane, 2,3,4-trisilylpentasilane, 2,3,4-trisilylpentasilane, 2,3-disilyltetrasilane, 2,2,3,3-tetrasilyltetrasilane, 2-silylhexasilane, 3-silylhexasilane, 3,4-disilylhexasilane, 2,3-disilylpentasilane, 2,4-disilylhexasilane, 4-silylheptasilane, 2,2-disilylpentasilane, 3,3-disilylpentasilane, 3,3-disilylhexasilane, 2,2-disilyhexasilane, 2,3-disilylhexsilane, 2-silylheptasilane, 3-silylheptasilane, 2,5-disilyhexasilane, 2,3,3-trisilylpentasilane, and/or the like), cyclic silane(s) (e.g., cyclotrisilane, cyclotetrasilane, cyclopentasilane, cyclohexasilane, cycloheptasilane, and so forth, as well as silyl-substituted variants thereof); and/or silicon hydrohalide(s), for example, monochlorosilane, dichlorosilane, trichlorosilane, 1,2-dichlorodisilane, 1,2,3-trichlorotrisilane and/or the like; and/or silicon halide(s), for example, silicon tetrachloride, silicon tetraiodide, silicon tetrabromide, hexachlorodisilane, octachlorotrisilane, and/or the like; and/or aminosilane(s), for example, hexakis(ethylamino)disilane, bis(diethylamino)silane, di-isopropylaminosilane, and/or the like; and/or oxysilane(s), for example, tetraethoxysilane; and/or germanium-containing precursor(s), such as germanium hydride(s), for example, germane, digermane, trigermane, tetragermane, pentagermane, and so forth, germanium hydrohalide(s), for example, dichlorogermane and/or trichlorogermane, germanium halide(s), for example, germanium tetrachloride, germanium tetrabromide, and/or hexachlorodigermane; and/or silicon-and germanium-containing precursor(s), for example, silicon-germanium hydride(s), such as germylsilane; and/or any at least partly deuterium-substituted variants of any of the above; and/or mixtures of any of the above.

The process of forming a second epitaxial layer of the embodiment of FIG. 1 may comprise exciting one or more reactants to form the second active species. In particular, the one or more reactants of the embodiment of FIG. 1 may comprise hydrogen gas. In other embodiments, a process of forming a second epitaxial layer may or may not comprise exciting one or more reactants to form second active species. Additionally or alternatively, in some embodiments the one or more reactants excited to form second active species may consist of, consist substantially or, or comprise any suitable reactant(s), for example, hydrogen gas, deuterium gas, helium, neon, and/or argon. In other embodiments, wherein a process of forming an epitaxial layer comprises exciting one or more reactants to form second active species, the process of forming a second epitaxial layer may or may not comprise supplying the one or more reactants into a process chamber. For example, in some embodiments, one or more reactants may be excited remotely outside of a process chamber to form second active species and the formed second active species may be transferred to the process chamber for forming a second epitaxial layer.

In the embodiment of FIG. 1, the second active species may comprise hydrogen radicals and hydrogen ions. In other embodiments, the second active species in whose presence a substrate is exposed to one or more precursors during a process of forming a second epitaxial layer may consist of, consist substantially or, or comprise any suitable active species, for example, hydrogen-containing, deuterium-containing, helium-containing, neon-containing, and/or argon-containing active species.

The process of forming a second epitaxial layer 12 of the embodiment of FIG. 1 may comprise maintaining a second plasma at a second plasma power per exposed substrate area of about 0.05 W/cm², 0.07 W/cm², 0.1 W/cm², 0.12 W/cm², or 0.15 W/cm² to generate the second active species. In other embodiments, a process of forming a second epitaxial layer may comprise maintaining a second plasma at any suitable plasma power per exposed substrate area, for example, a plasma power per exposed substrate area greater than or equal to 0.01 W/cm², or to 0.02 W/cm², or to 0.03 W/cm², or to 0.04 W/cm², or to 0.05 W/cm² and/or less than or equal to 0.1 W/cm², or to 0.13 W/cm², or to 0.15 W/cm², or to 0.17 W/cm², or to 0.2 W/cm², or to 0.5 W/cm², or to 1 W/cm², or to 2 W/cm² to generate the active species.

In the embodiment of FIG. 1, the process of forming a second epitaxial layer 12 may comprise generating the second active species 15 in the process chamber. In other embodiments, a process of forming a second epitaxial layer may comprise generating the second active species in any suitable manner and/or at any suitable location. For example, in some embodiments, a process of forming a second epitaxial layer may comprise generating the second active species in a process chamber and/or outside of the process chamber. In some embodiments, a process of forming a second epitaxial layer may comprise generating the second active species using an in-situ plasma source and/or a remote plasma source. In embodiments, wherein a process of forming a second epitaxial layer comprises generating the second active species in a process chamber and/or using an in-situ plasma source, the active species may be generated using any suitable technique(s) or device(s), for example, radio-frequency plasma source(s), e.g., capacitively coupled plasma source(s) and/or inductively coupled plasma source(s); microwave plasma source(s), e.g., electron cyclotron resonance plasma source(s); surface wave plasma source(s), and/or the like. In embodiments, wherein a process of forming a second epitaxial layer comprises generating the second active species outside of a process chamber and/or using a remote plasma source, the active species may be generated using any suitable technique(s) or device(s), for example, radio-frequency plasma source(s), e.g., capacitively coupled plasma source(s) and/or inductively coupled plasma source(s); microwave plasma source(s), e.g., electron cyclotron resonance plasma source(s); surface wave plasma source(s), and/or the like.

The process of forming a second epitaxial layer 12 of the embodiment of FIG. 1 may comprise maintaining a second deposition temperature 16 of about 200 Pa, or 250 Pa, or 300 Pa in the process chamber. In some embodiments, maintaining a suitable second deposition pressure during a process of forming a second epitaxial layer may enable tuning a distribution of active species in the vicinity of a substrate. Additionally or alternatively, in some embodiments maintaining a suitable second deposition pressure during a process of forming a second epitaxial layer may increase a growth rate of a second epitaxial layer. Additionally or alternatively, in some embodiments maintaining a suitable second deposition pressure during a process of forming a second epitaxial layer may increase a crystallinity of a second epitaxial layer. Additionally or alternatively, in some embodiments maintaining a suitable second deposition pressure during a process of forming a second epitaxial layer may reduce etching while forming a second epitaxial layer. In other embodiments, a process of forming a second epitaxial layer may comprise maintaining any suitable second deposition pressure, for example, a second deposition pressure greater than or equal to 160 Pa, or to 200 Pa, or to 240 Pa, or to 280 Pa and/or less than or equal to 420 Pa, or to 460 Pa, or to 500 Pa, in a process chamber.

In the embodiment of FIG. 1, the process of forming a second epitaxial layer 12 may comprise maintaining a second deposition temperature 17 of about 200° C., 350° C., or 500° C. In some embodiments, maintaining a suitable second deposition temperature may increase a growth rate of a second epitaxial layer. Additionally or alternatively, in some embodiments, maintaining a suitable second deposition temperature may increase a crystallinity of a second epitaxial layer. Additionally or alternatively, in some embodiments, maintaining a suitable second deposition temperature may facilitate forming a second epitaxial layer with reduced interlayer diffusion. Additionally or alternatively, in some embodiments maintaining a sufficiently low second deposition temperature may reduce total energy consumption of a method for forming an epitaxial structure onto a substrate. In other embodiments, a process of forming a second epitaxial layer may comprise maintaining any suitable second deposition temperature, for example, a second deposition temperature greater than or equal to 100° C., or to 120° C., or to 150° C. and/or less than or equal to 180° C., or to 190° C., or to 200° C., or to 250° C., or to 300° C., or to 400° C., or to 500° C., or to 600° C., or to 700° C.

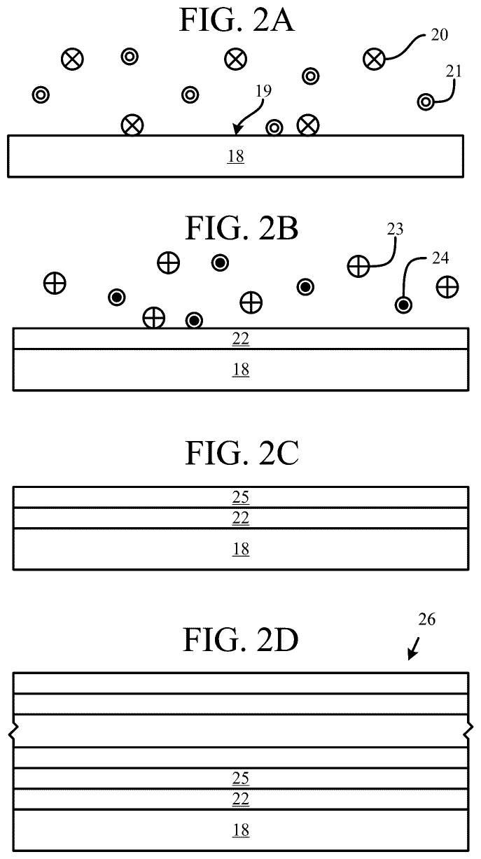

FIG. 2A, FIG. 2B, FIG. 2C, and FIG. 2D schematically illustrate a series of successive stages of a method for forming an epitaxial structure onto a substrate according to an embodiment. Unless explicitly stated otherwise, the method for forming an epitaxial structure onto a substrate of the embodiment of FIGS. 2A-2D may or may not comprise any feature(s) disclosed within this specification, mutatis mutandis. Other embodiments may or may not be identical or similar to the embodiment of FIGS. 2A-2D.

FIG. 2A shows a substrate 18 having an exposed face 19 exposed in a process chamber to at least one precursor 20 in the presence of active species 21 to form an epitaxial layer 22 onto the substrate 18. In FIG. 2A, the at least one precursor 20 is schematically depicted as a collection of circled crosses, whereas the active species 21 are schematically portrayed as a collection of circled white bullets. FIG. 2B depicts the epitaxial layer 22 on the substrate 18 and shows the epitaxial layer 22 being exposed in the process chamber to one or more precursors 23 in the presence of second active species 24 to form a second epitaxial layer 25 onto the epitaxial layer 22. In FIG. 2B, the one or more precursors 23 is schematically depicted as a collection of circled plusses, whereas the second active species 24 are schematically portrayed as a collection of circled bullets. FIG. 2C shows the substrate 18, the epitaxial layer 22 overlaying the substrate 18, and the second epitaxial layer 25 overlaying the epitaxial layer 22. Finally, FIG. 2D depicts an epitaxial structure 26, more specifically an epitaxial superlattice, which may have been formed, for example, by periodically (e.g., alternatingly) or non-periodically repeating processes of forming an epitaxial layer and/or forming a second epitaxial layer. In such case, the substrate 18 and any previously formed layer(s) may effectively function as a substrate onto which new epitaxial layer(s) are formed. Additionally or alternatively, a previously formed and exposed epitaxial layer may effectively function as an epitaxial layer onto which a new second epitaxial layer may be formed. In the embodiment of FIGS. 2A-2D, the substrate 18 has one exposed face 19. In other embodiments, each substrate provided in a process chamber may independently have any suitable number of exposed faces, e.g., one or two.

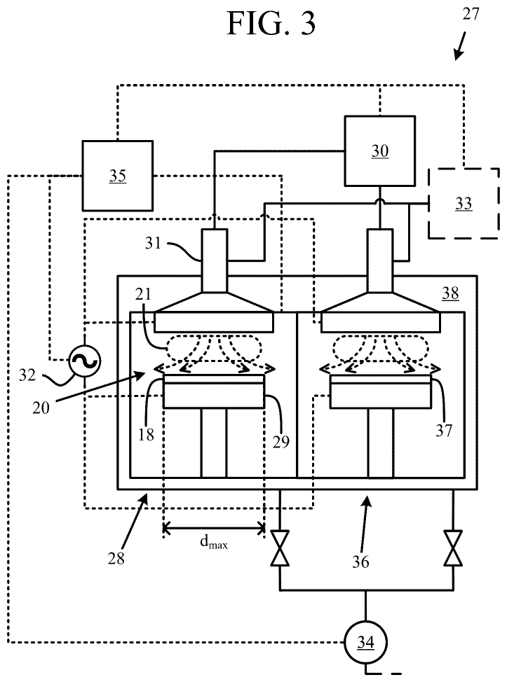

FIG. 3 schematically illustrates a substrate processing apparatus 27 according to an embodiment. Unless explicitly stated otherwise, the substrate processing apparatus 27 of the embodiment of FIG. 3 may or may not comprise any feature(s) disclosed within this specification, mutatis mutandis. Other embodiments may or may not be identical or similar to the embodiment of FIG. 3.

In the embodiment of FIG. 3, the substrate processing apparatus 27 comprises a process chamber 28 configured to hold a substrate 18. The process chamber 28 of the embodiment of FIG. 3 comprises a substrate holder 29, such as a temperature-controlled susceptor, for holding the substrate 18. In other embodiments, wherein a process chamber is configured to hold a substrate, the process chamber may or may not comprise a susceptor. For example, in some embodiments, a process chamber may comprise a wafer boat for holding one or more substrates.

The substrate holder 29 of the embodiment of FIG. 3 is configured to hold a semiconductor wafer having a maximum diameter dₘₐₓ of about 300 mm. In other embodiments, wherein a process chamber comprises a substrate holder, the substrate holder may be configured to hold any suitable substrate(s), for example, one or more rectangular wafers, which may or may not have a size of about 510 mm×515 mm; or one or more circular wafers, which may or may not have a maximum diameter of about 200 mm, about 300 mm, or about 450 mm.

The substrate processing apparatus 27 of the embodiment of FIG. 3 comprises a precursor source 30 for providing at least one precursor 20 in the process chamber 28. The process chamber 28 comprises a showerhead injector 31, and the precursor source 30 is configured to supply the at least one precursor 20 into the process chamber 28 via the showerhead injector 31. In other embodiments, a process chamber may or may not comprise a showerhead injector, and/or a precursor source may or may not be configured to supply at least one precursor into a process chamber such showerhead injector. For example, in some embodiments, a precursor source may be configured to supply at least one precursor into a process chamber in a so-called cross-flow configuration, wherein the at least one precursor is directed to flow along the extent of a substrate via one or more precursors inlets and/or one or more precursor outlets.

In the embodiment of FIG. 3, the substrate processing apparatus 27 comprises a plasma source 32 for providing active species 21 in the process chamber 28. As indicated in FIG. 2 using dashed arrows, the plasma source 32 is electrically coupled to the substrate holder 29 and the showerhead injector 31 for applying radio-frequency power therebetween to generate the active species 21 in the process chamber 28. In other embodiments, a plasma source may or may not be electrically coupled to a substrate holder and/or a showerhead injector for providing active species in the process chamber. For example, in some embodiments, a plasma source may be configured for generating active species outside of a process chamber and to transfer the active species into the process chamber. Further, in some embodiments, a plasma source may be configured to generate active species using one or more plasma formation techniques, which do not require applying radio-frequency power between a substrate holder and a showerhead injector.

The substrate processing apparatus 27 of the embodiment of FIG. 3 further comprises a control unit 35. As indicated in FIG. 2 using dashed arrows, the control unit 35 is operably coupled to the process chamber 28, the precursor source 30, and the plasma source 32. The control unit 35 is configured to cause the substrate processing apparatus 27 to perform a method in accordance with the first aspect described above.

As indicated in FIG. 2 using dashed lines, the substrate processing apparatus 27 of the embodiment of FIG. 3 may further comprise a reactant source 33 for providing one or more reactants, such as hydrogen, deuterium, argon, helium, or any mixture thereof, in the process chamber 28. The reactant source 33 may be configured to supply the one or more reactants into the process chamber 28 via the showerhead injector 31. The control unit 35 may be further operably coupled to the reactant source 33 and configured to cause the plasma source 32 to generate the active species 21 while the reactant source 33 supplies the one or more reactants into the process chamber 28. In other embodiments, a substrate processing apparatus may or may not comprise a reactant source. For example, in some embodiments, active species may form via excitation and/or dissociation of at least one precursor, for example, when subjected to a high-power radio-frequency electromagnetic field.

The substrate processing apparatus 27 of the embodiment of FIG. 3 comprises an exhaust pump 34 fluidically coupled to the process chamber 28 for evacuating the process chamber 28. The control unit 35 may be further operably coupled to the exhaust pump 34 and configured for purging the process chamber 28 by operating the exhaust pump 34 and, optionally, the reactant source and/or a separate purging or cleaning gas source, which is not depicted in FIG. 2 for improved clarity.

In the embodiment of FIG. 3, the substrate processing apparatus 27 is configured for concurrently forming an epitaxial layer onto the substrate and forming one or more further epitaxial layers onto one or more further substrates 37. The substrate processing apparatus 27 comprises a one or more further process chambers 36 configured to hold the one or more further substrates 37, the precursor source 30 is configured for providing the at least one precursor 20 in the one or more further process chambers 36, the plasma source 32 is configured for providing active species 21 in the one or more further process chambers 36, and the control unit 35 is operably coupled further with the one or more further process chambers 36 to cause the substrate processing apparatus 27 to perform a method in accordance with the first aspect described above also using the one or more further process chambers 36. The reactant source 33 may be configured for providing the one or more reactants also in the one or more further process chambers 36, and/or the exhaust pump 34 may be fluidically coupled to the one or more further process chambers 36 for evacuating the one or more further process chambers 36. In other embodiments, wherein a substrate processing apparatus is configured for concurrently forming an epitaxial layer onto a substrate and forming one or more further epitaxial layers onto one or more further substrates, the substrate processing apparatus may or may not comprise one or more further process chambers. For example, in some embodiments, a substrate processing apparatus may comprise a process chamber configured to hold a substrate as well as one or more further substrates, whereby the substrate and the one or more further substrates may be simultaneously processed in the process chamber in a batch process. In other embodiments, wherein a substrate processing apparatus is configured for concurrently forming an epitaxial layer onto a substrate and forming one or more further epitaxial layers onto one or more further substrates and comprises a process chamber and one or more further process chambers, the process chamber and at least part of the one or more further process chambers may or may not be operated using the same precursor source, plasma source, control unit, reactant source, and/or exhaust pump.

In the embodiment of FIG. 3, the process chamber 28 and the one or more further process chambers 36 are held by a common frame 38. As such, the substrate processing apparatus 27 of the embodiment of FIG. 3 may be referred to as a multi-chamber substrate processing module. In general, when a substrate processing apparatus comprises two or four process chambers held by a common frame, the substrate processing apparatus may be referred to as a dual-chamber or quad-chamber substrate processing module, respectively. In case the substrate processing apparatus 27 of the embodiment of FIG. 3 comprises a total of two process chambers held by a common frame, the substrate processing apparatus 27 may be implemented as a dual-chamber substrate processing module. In other embodiments, a substrate processing apparatus may or may not be implemented as a multi-chamber (e.g., dual-chamber or quad-chamber) substrate processing module. For example, in some embodiments, a substrate processing apparatus may comprise one or more process chambers held by separate frames.

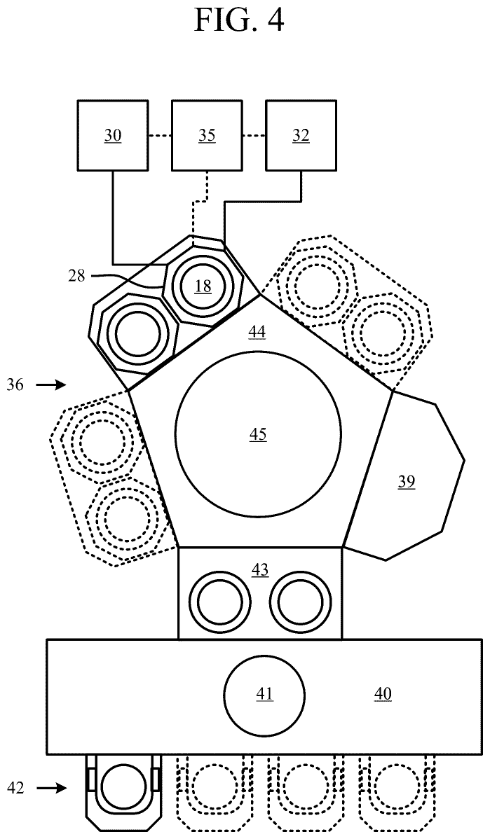

FIG. 4 schematically illustrates a substrate processing apparatus 27 according to another embodiment. Unless explicitly stated otherwise, the substrate processing apparatus 27 of the embodiment of FIG. 4 may or may not comprise any feature(s) disclosed within this specification, mutatis mutandis. Other embodiments may or may not be identical or similar to the embodiment of FIG. 4.

The substrate processing apparatus 27 of the embodiment of FIG. 4 comprises a process chamber 28 configured to hold a substrate 18, a precursor source 30 for providing at least one precursor in the process chamber 28, and a plasma source 32 for providing active species in the process chamber 28. The substrate processing apparatus 27 further comprises a control unit 35 operably coupled to at least the process chamber 28, the precursor source 30, and the plasma source 32. The control unit 35 is configured to cause the substrate processing apparatus 27 to perform a method in accordance with the first aspect discussed above.

In some embodiments, a control unit may be configured to cause a substrate processing apparatus to perform a method in accordance with the first aspect by running a computer program. In some embodiments, a computer program may include instructions that, when executed by a processor, cause a substrate processing apparatus to perform a method in accordance with the first aspect. In some embodiments, a computer program may be written in a high-level programming language compatible with a control unit of a substrate processing apparatus, be modular, and/or consist of a plurality of software components, such as a user interface module, a process control module, and/or a data logging module. Generally, a user interface module may provide a graphical user interface (GUI) and/or allow operators to input process parameters, monitor real-time data, and/or adjust process settings as needed. Additionally or alternatively, a process control module may manage the timing and/or sequence of precursor and active species delivery, ensuring suitable conditions for epitaxial layer formation. Additionally or alternatively, a data logging module may record process parameters, system status, and/or any anomalies for future analysis and quality control. In some embodiments, a computer program may include one or more algorithms to dynamically adjust flow rates of specific precursors and/or a power of one or more plasma sources based on real-time feedback from one or more sensors arranged within one or more process chambers. In some embodiments, a computer program may can execute predefined recipes for distinct types of epitaxial layers, which may increase consistency and/or repeatability across multiple runs. In some embodiments, a computer program may be designed to be compatible with various types of substrate processing apparatuses, facilitating integration into existing substrate processing apparatuses. For example, in some embodiments, a computer program may support multiple communication standards (e.g., Ethernet and/or RS-232) for seamless interaction with other equipment and control systems. In some embodiments, a computer program may be updated remotely, which may enable the addition of new features and improvements without significant substrate processing apparatus downtime.

In some embodiments, a computer program configured to cause a substrate processing apparatus in accordance with the second aspect to execute a method in accordance with the first aspect may be stored on a computer-readable medium, for example, a non-transitory computer-readable medium. In some embodiments, a non-transitory computer-readable medium may retain stored data in the absence of a continuous power supply. Examples of non-transitory computer-readable media may include, but are not necessarily limited to, hard drives, solid-state drives (SSDs), optical discs (CDs, DVDs, and Blu-ray discs), flash memory devices (USB drives and memory cards), and magnetic tapes.

In the embodiment of FIG. 4, the substrate processing apparatus 27 comprises a preclean chamber 39 coupled with the process chamber 28 to allow transferring the substrate 18 from the preclean chamber 39 to the process chamber 28 under vacuum. The substrate processing apparatus 27 further comprises a substrate transfer chamber 44, which is provided with a back-end substrate transfer robot 45, connected to the process chamber 28 and the preclean chamber 39. While transferring the substrate 18 from the preclean chamber 39 to the process chamber 28 via the substrate transfer chamber 44, the substrate processing apparatus 27 is configured to maintain a vacuum in the substrate transfer chamber 44, whereby the substrate 18 may be transferred from the preclean chamber 39 to the process chamber 28 under vacuum. In other embodiments, a substrate processing apparatus may or may not comprise a substrate transfer chamber connected to a process chamber and/or a preclean chamber. In other embodiments, wherein a substrate processing apparatus comprises a preclean chamber coupled with a process chamber to allow transferring the substrate from the preclean chamber to the process chamber, for example, under vacuum or under an inert gas (e.g., argon, helium, and/or nitrogen) ambient, the substrate may be transferred from the preclean chamber to the process chamber directly or indirectly, e.g., via a substrate transfer chamber or the like.

In the embodiment of FIG. 4, the substrate processing apparatus 27 further comprises an equipment front-end module 40, which may be provided with a front-end substrate transfer robot 41 and one or more substrate load ports 42, and a loadlock module 43 connecting the equipment front-end module 40 and the substrate transfer chamber 44 for transferring the substrate 18 therebetween. In other embodiments, a substrate processing apparatus may or may not comprises such an equipment front-end module and/or such a loadlock module.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method for forming an epitaxial structure onto a substrate, the method comprising:
providing the substrate in a process chamber; and
forming an epitaxial layer onto the substrate by exposing the substrate in the process chamber to at least one precursor in the presence of active species,
wherein the forming an epitaxial layer comprises maintaining a plasma at a plasma power per exposed substrate area less than or equal to 0.2 W/cm² to generate the active species.

2. A method claim 1, wherein the epitaxial structure is implemented as an epitaxial superlattice.

3. A method claim 1, wherein the epitaxial layer comprises crystalline silicon.

4. A method claim 1, wherein the epitaxial layer has a layer thickness greater than or equal to 1 nm or to 3 nm, or to 5 nm and/or less than or equal to 10 nm, or to 20 nm, or to 30 nm, or to 40 nm, or to 50 nm.

5. A method claim 1, wherein the substrate comprises a semiconductor wafer, such as a silicon wafer.

6. A method according to claim 5, wherein the semiconductor wafer has a diameter of about 200 mm, about 300 mm, or about 450 mm.

7. A method claim 1, wherein the at least one precursor comprises silane.

8. A method claim 1, wherein the forming an epitaxial layer comprises exciting at least one reactant to form the active species.

9. A method claim 8, wherein the at least one reactant comprises hydrogen gas.

10. A method claim 1, wherein the active species comprise hydrogen radicals and/or hydrogen ions.

11. A method claim 1, wherein the forming an epitaxial layer comprises maintaining a plasma at a plasma power per exposed substrate area greater than or equal to 0.01 W/cm², or to 0.02 W/cm², or to 0.03 W/cm², or to 0.04 W/cm², or to 0.05 W/cm² and/or less than or equal to 0.1 W/cm², or to 0.13 W/cm², or to 0.15 W/cm², or to 0.17 W/cm² to generate the active species.

12. A method claim 1, wherein the forming an epitaxial layer comprises generating the active species in the process chamber.

13. A method claim 1, wherein the forming an epitaxial layer comprises maintaining a deposition pressure greater than or equal to 160 Pa, or to 200 Pa, or to 240 Pa, or to 280 Pa and/or less than or equal to 420 Pa, or to 460 Pa, or to 500 Pa in the process chamber.

14. A method claim 1, wherein the forming an epitaxial layer comprises maintaining a deposition temperature greater than or equal to 100 ° C., or to 120 ° C., or to 150 ° C. and/or less than or equal to 180 ° C., or to 190 ° C., or to 200 ° C., or to 250 ° C., or to 300 ° C., or to 400 ° C., or to 500 ° C., or to 600 ° C., or to 700 ° C. in the process chamber.

15. A method claim 1, wherein the method comprises precleaning the substrate prior to the forming an epitaxial layer.

16. A method according to claim 15, wherein the precleaning the substrate comprises providing the substrate in a preclean chamber, and the providing the substrate in a process chamber comprises transferring the substrate from the preclean chamber to the process chamber under vacuum.

17. A method claim 1, wherein the method comprises forming a second epitaxial layer onto the epitaxial layer by exposing the epitaxial layer in the process chamber to one or more precursors in the presence of second active species.

18. A method according to claim 17, wherein the second epitaxial layer comprises silicon germanium.

19. A method according to claim 17, wherein the second epitaxial layer has a layer thickness greater than or equal to 1 nm or to 3 nm, or to 5 nm and/or less than or equal to 10 nm, or to 20 nm, or to 30 nm, or to 40 nm, or to 50 nm.

20. A method according to claim 17, wherein the one or more precursors comprises silane and germane.

21. A method according to claim 17, wherein the forming a second epitaxial layer comprises exciting one or more reactants to form the second active species.

22. A method according to claim 21, wherein the one or more reactants comprises hydrogen gas.

23. A method according to claim 17, wherein the second active species comprise hydrogen radicals and/or hydrogen ions.

24. A method according to claim 17, wherein the forming a second epitaxial layer comprises maintaining a second plasma at a second plasma power per exposed substrate area greater than or equal to 0.01 W/cm², or to 0.02 W/cm², or to 0.03 W/cm², or to 0.04 W/cm², or to 0.05 W/cm² and/or less than or equal to 0.1 W/cm², or to 0.13 W/cm², or to 0.15 W/cm², or to 0.17 W/cm², or to 0.2 W/cm², or to 0.5 W/cm², or to 1 W/cm², or to 2 W/cm² to generate the second active species.

25. A method according to claim 17, wherein the forming a second epitaxial layer comprises generating the second active species in the process chamber.

26. A method according to claim 17, wherein the forming a second epitaxial layer comprises maintaining a second deposition pressure greater than or equal to 160 Pa, or to 200 Pa, or to 240 Pa, or to 280 Pa and/or less than or equal to 420 Pa, or to 460 Pa, or to 500 Pa in the process chamber.

27. A method according to claim 17, wherein the forming a second epitaxial layer comprises maintaining a second deposition temperature greater than or equal to 100 ° C., or to 120 ° C., or to 150 °C and/or less than or equal to 180 ° C., or to 190 ° C., or to 200 ° C., or to 250 ° C., or to 300 ° C., or to 400 ° C., or to 500 ° C., or to 600 ° C., or to 700 ° C. in the process chamber.

28. A substrate processing apparatus, comprising:
a process chamber configured to hold a substrate,
a precursor source for providing at least one precursor in the process chamber, and
a plasma source for providing active species in the process chamber, wherein the substrate processing apparatus comprises a control unit operably coupled to at least the process chamber, the precursor source, and the plasma source, the control unit configured to cause the substrate processing apparatus to perform a method comprising:
providing the substrate in the process chamber; and
forming an epitaxial layer onto the substrate by exposing the substrate in the process chamber to the at least one precursor in the presence of active species,
wherein the forming an epitaxial layer comprises maintaining a plasma at a plasma power per exposed substrate area less than or equal to 0.2 W/cm² to generate the active species.

29. A substrate processing apparatus according to claim 28, wherein the substrate processing apparatus is configured for concurrently forming an epitaxial layer onto the substrate and forming one or more further epitaxial layers onto one or more further substrates.

30. A substrate processing apparatus according claim 28, wherein the process chamber comprises a substrate holder configured to hold a semiconductor wafer having a maximum diameter of about 200 mm, about 300 mm, or about 450 mm.

31. A substrate processing apparatus according to claim 28, wherein the substrate processing apparatus comprises a reactant source for providing one or more reactants in the process chamber.

32. A substrate processing apparatus according to claim 28, wherein the substrate processing apparatus comprises a preclean chamber coupled with the process chamber to allow transferring the substrate from the preclean chamber to the process chamber under vacuum.

33. A non-transitory computer-readable medium storing a computer program that, when executed by a computer, performs a method for forming an epitaxial structure onto a substrate, the method comprising:
providing the substrate in a process chamber; and
forming an epitaxial layer onto the substrate by exposing the substrate in the process chamber to at least one precursor in the presence of active species,
wherein the forming an epitaxial layer comprises maintaining a plasma at a plasma power per exposed substrate area less than or equal to 0.2 W/cm² to generate the active species.
